(19) United States
(12) Patent Application Publication
(10) Pub. No.: US 2026/0148925 A1
(43) Pub. Date: May 28, 2026

(54) ION IMPLANTER

(71) Applicant: ADVANCED ION BEAM TECHNOLOGY, INC., HsinChu City (TW)

(72) Inventor: Yu-Teng Lai, HsinChu City (TW)

(73) Assignee: ADVANCED ION BEAM TECHNOLOGY, INC., HsinChu City (TW)

(21) Appl. No.: 19/396,908

(22) Filed: Nov. 21, 2025

(30) Foreign Application Priority Data
Nov. 25, 2024 (TW) 113145393

(51) Int. Cl. H01J 37/15; H01J 37/317

(52) U.S. Cl. CPC H01J 37/15; H01J 37/3171

(57) ABSTRACT

An ion implanter includes an ion source, a linear multipole module, an ion beam shape adjustment module, and an analyzer magnet unit. The linear multipole module is positioned between the ion source and a substrate. The ion beam shape adjustment module is positioned between the ion source and the linear multipole module. The analyzer magnet unit is positioned between the ion source and the linear multipole module, the ion beam shape adjustment module is positioned in front of an entrance of the analyzer magnet unit, and the linear multipole module is positioned behind an exit of the analyzer magnet unit. The ion beam shape adjustment module is configured to adjust an ion beam to modify an ion beam divergence angle as the ion beam enters the substrate.

### CROSS-REFERENCE TO RELATED APPLICATION

This non-provisional application claims priority under 35 U.S.C. § 119 (a) to patent application No. 113145393 filed in Taiwan, R.O.C. on Nov. 25, 2024, the entire contents of which are hereby incorporated by reference.

### BACKGROUND

### Technical Field

The present disclosure relates to an ion implanter, and in particular to an ion implanter capable of adjusting an ion beam height.

### Related Art

In the field of semiconductor manufacturing, the influence of precise control of ion beam parameters on ion implantation in a substrate is critical. When an ion beam is emitted from an arc slit of an ion source, and if a height of the ion beam is insufficient, it will not be able to effectively cover the diameter of a substrate. Therefore, it is needed to adjust the ion beam height to ensure the ion beam completely covering the diameter of a substrate. In general, an ion implanter adjusts the divergence of the ion beam by generating a magnetic field, thereby changing the covered height or width of the ion beam.

However, although existing devices solve the problem of insufficient ion beam height through a magnetic field, it inevitably introduces another problem, that is, a divergent angle of the ion beam increases. The divergent angle of the ion beam is related to the component of the ion beam travelling direction vertical to the substrate and parallel to the substrate, and when the ion beam has a large divergent angle, it will lead to differences of implantation depth in different areas of the substrate. Specifically, this phenomenon is reflected in the ion beam directed to a center of the substrate wherein the ion beam has a large component of a travelling speed vertical to the substrate, and it has a deeper implantation depth. In contrast, the ion beam at an edge of the substrate has a smaller component of the travelling speed vertical to the substrate, and it has a shallower implantation depth. This differences in implantation depth pose a challenge to achieve substrate process uniformity.

### SUMMARY

In view of this, the applicant provides an ion implanter configured to process a substrate. The ion implanter includes: an ion source, a linear multipole module, an ion beam shape adjustment module, and an analyzer magnet unit. The ion source is configured to generate an ion beam. The linear multipole module is positioned between the ion source and the substrate and configured to diverge the ion beam. The ion beam shape adjustment module is positioned between the ion source and the linear multipole module. The analyzer magnet unit is positioned between the ion source and the linear multipole module, the ion beam shape adjustment module is positioned in front of an entrance of the analyzer magnet unit, and the linear multipole module is positioned behind an exit of the analyzer magnet unit. The ion beam shape adjustment module can be configured to adjust the ion beam to modify an ion beam divergence angle as the ion beam enters the substrate.

### BRIEF DESCRIPTION OF THE DRAWINGS

FIG. 1 is a schematic diagram of an ion implanter according to an Embodiment I.

FIG. 2 is a schematic diagram of an operating state of an ion beam profiler according to some embodiments.

FIG. 3A is a schematic diagram of a coverage range of an ion beam height according to some embodiments.

FIG. 3B is a schematic diagram of divergent angles of an ion beam in different axis directions according to some embodiments.

FIG. 4 is a top view schematic diagram of an angle measurement Faraday cup of an ion beam profiler according to some embodiments.

FIG. 5A is a schematic diagram of a central angle of an ion beam according to some embodiments.

FIG. 5B is a schematic diagram of a divergent angle of an ion beam according to some embodiments.

FIG. 6 is a schematic diagram of an ion implanter according to an Embodiment II.

FIG. 7 is a schematic diagram of an ion beam shape adjustment module according to some embodiments.

FIG. 8 is a schematic diagram of a plurality of magnetic field measurement points among ion beam shape adjustment modules according to some embodiments.

FIG. 9 is a three-dimensional schematic diagram of a vacuum chamber according to an Embodiment III.

FIG. 10 is a front view schematic diagram of a vacuum chamber according to an Embodiment III.

FIG. 11 is a three-dimensional schematic diagram of an ion beam shape adjustment module according to an Embodiment III.

FIG. 12 is a front view schematic diagram of an ion beam shape adjustment module according to an Embodiment III.

FIG. 13 is a top view schematic diagram of an ion beam shape adjustment module according to an Embodiment III.

FIG. 14 is a three-dimensional schematic diagram of a driver of an ion beam shape adjustment module according to an Embodiment III.

FIG. 15 is a three-dimensional schematic diagram of a vacuum chamber according to an Embodiment IV.

FIG. 16 is a front view schematic diagram of a vacuum chamber according to an Embodiment IV.

FIG. 17 is a front view schematic diagram of a driver of an ion beam shape adjustment module according to an Embodiment IV.

### DETAILED DESCRIPTION

Unless otherwise specified, when the terms “comprise”, “include” or “has” are used, the contents of this description may include other elements, components, structures, areas, parts, apparatuses, systems, procedures, connections, etc., and shall not exclude other specifications. When the terms “upper”, “top”, “lower”, “bottom”, “left”, “right”, “inner”, “outer”, “near” and “far” are used only for illustrating the technical content or relative relationship of the embodiments of the present disclosure, and are not used for limiting the scope of application of the present disclosure unless otherwise specified. Therefore, any adjustment, exchange or change of relative position and relationship, as long as it does not substantially change the technical content of the present disclosure, should fall within the scope of the claims of the present disclosure. When the order of the terms “first” and “second” is used, it is only for the purpose of describing or distinguishing specifications such as elements, components, structures, areas, parts, apparatuses, and systems, and the purpose is not to limit the scope of application of the present disclosure, nor to limit the spatial order relationship between such specifications. In addition, unless otherwise specified, the singular term “one” in this description also applies to the situation of plurality in use, and the terms “or” and “and/or” may be used interchangeably.

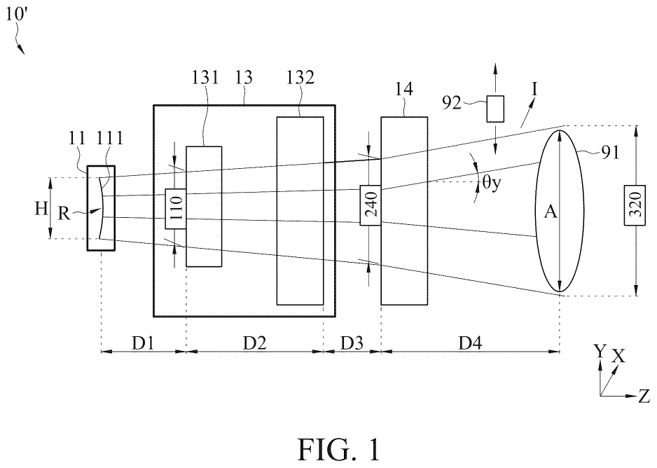

FIG. 1 is a schematic diagram of an ion implanter according to an Embodiment I, and FIG. 1 is used for reference. In the embodiment, an ion implanter 10′ includes an ion source 11, an analyzer magnet unit 13 and a linear multipole module 14. The ion implanter 10′ is configured to process a substrate 91, such as an ion implantation process of a wafer. The linear multipole module 14 is positioned between the ion source 11 and the substrate 91, and the analyzer magnet unit 13 is positioned between the ion source 11 and the linear multipole module 14.

The ion source 11 is configured to generate a charged ion beam I, and the ion beam I includes dopant ions to be implanted into the substrate 91. The ion beam I generated by the ion source 11 is emitted to the substrate 91 through an arc slit 111. The analyzer magnet unit 13 (AMU) separates ions with different valence numbers and masses (such as isotopes) in the charged ion beam I through a magnetic field, and therefore target dopant ions are analyzed. In order to effectively separate the ion beam I, the analyzer magnet unit 13 needs to provide a long travelling distance for the ion beam I. The linear multipole module 14 (LMP) may include an electromagnet array including a plurality of coils, the array changes a travelling direction of the charged ion beam I by generating the magnetic field, and therefore the convergence or divergence effect similar to a lens is achieved. Therefore, the ion implanter 10′ can be configured to adjust a height of the ion beam I. In detail, in some embodiments, the charged ion beam I generated by the ion source 11 is a ribbon beam having an ion beam width and an ion beam height. In the embodiment, the ion beam width refers to a distribution amplitude of the ribbon beam in a coordinate axis X direction, the ion beam height refers to a distribution amplitude of the ribbon beam in a coordinate axis Y direction, and the distribution amplitude of the ribbon beam in the coordinate axis Y direction is larger than the distribution amplitude in the coordinate axis X direction. The ion implanter 10′ can diverge the ribbon beam in the coordinate axis Y direction so as to increase the ion beam height. It is to be known that in other embodiments, the ion beam height may also refer to the distribution amplitude of the ribbon beam in other axis directions, such as a coordinate axis X.

In FIG. 1, the arc slit 111 has a curvature R and a slit height H, thus, the emitted ion beam I has an initial divergent angle. The ion beam height of the ion beam I reaching an entrance 131 of the analyzer magnet unit 13 has a forward relationship with the curvature R and the slit height H of the arc slit 111, and it also has a forward relationship with a distance D1 between the arc slit 111 and the entrance 131 of the analyzer magnet unit 13. In other words, when the slit height H of the arc slit 111 is larger, the curvature R is larger or the distance D1 is longer, the height of the ion beam I reaching the entrance 131 of the analyzer magnet unit 13 is higher.

In addition, the inside of the analyzer magnet unit 13 has a long travelling distance D2 for the ion beam I, so that the ion beam height of the ion beam I entering the entrance 131 of the analyzer magnet unit 13 is 110 mm in this embodiment. The ion beam I further passes through the distance D2 in the analyzer magnet unit 13, a distance D3 between an exit 132 of the analyzer magnet unit 13 and the linear multipole module 14, and reaches the linear multipole module 14, wherein the ion beam height is increased to be 240 mm.

Then, the linear multipole module 14 diverges the ion beam I through magnetic field, so that the ion beam height of the ion beam I is increased from 240 mm before entering the linear multipole module 14 to 320 mm when reaching the substrate 91. The ion beam height of the ion beam I leaving the linear multipole module 14 is related to an ion beam divergent angle θy and a travelling distance D4, namely the ion beam height (240 mm according to this embodiment) of the ion beam I entering the linear multipole module 14 plus twice of the product of a tangent value of the ion beam divergence angle θy and the travelling distance D4 is equivalent to the ion beam height (320 mm according to this embodiment) of the ion beam I reaching the substrate 91. When the ion beam height of the ion beam I is increased, the range of the ion beam I covering the substrate 91 is increased. However, due to the space limitation of a semiconductor plant, a processing area range and a vacuum maintenance cost, the space in the ion implanter 10′ cannot be sufficiently expanded to increase the travelling distance of the ion beam I leaving the linear multipole module 14 to the substrate 91. Therefore, how to effectively utilize the limited space in the ion implanter 10′ and change the ion beam divergence angle θy is the key to adjust the ion beam height of the ion beam I in order to increase the coverage range of the ion beam I.

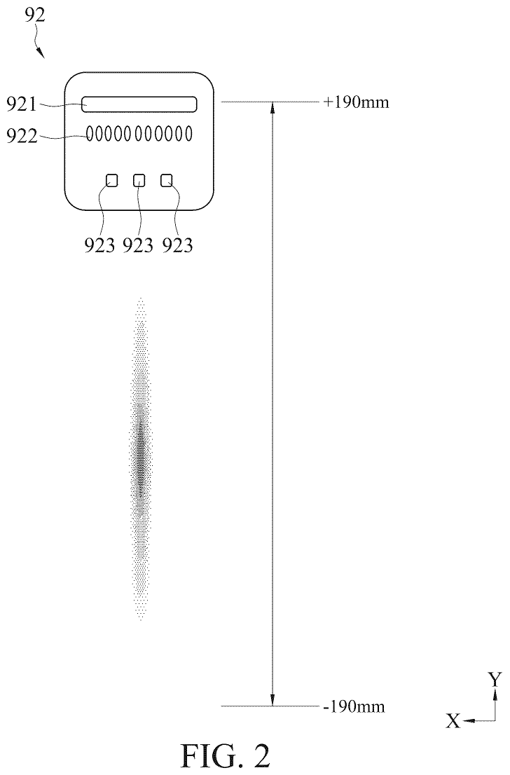

FIG. 2 is a schematic diagram of an operating state of an ion beam profiler according to some embodiments, and FIG. 1 and FIG. 2 are used for reference. In some embodiments, an ion beam profiler 92 can be positioned in front of the substrate 91, and can move along the coordinate axis Y direction to scan the ion beam I. In the embodiment, the ion beam profiler 92 includes three types of Faraday cup, namely a one-dimensional ion beam profile Faraday cup 921, a two-dimensional ion beam profile Faraday cup 922 and an angle measurement Faraday cup 923. The ion beam profiler 92 can include a plurality of angle measurement Faraday cups 923, such as three angle measurement Faraday cups 923 in the embodiment.

The one-dimensional ion beam profile Faraday cup 921 of the ion beam profiler 92 can be configured to measure the coverage range of the ion beam I. In order to facilitate understanding of subsequent technical content, the following first explains measurement methods for the height coverage range and divergence angle of the ion beam I.

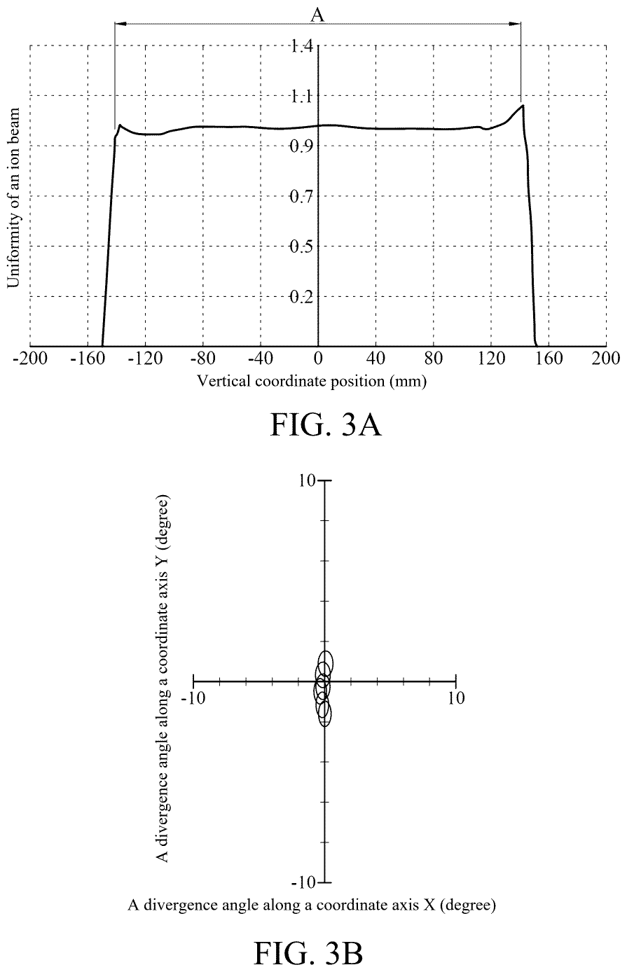

FIG. 3A is a schematic diagram of a coverage range of an ion beam height according to some embodiments, and FIG. 1 and FIG. 3A are used for reference. The horizontal axis in FIG. 3A represents the vertical coordinate positions along the path traversed by the surface of the ion beam profiler 92 during the scanning of the ion beam's long axis, and a longitudinal axis represents an uniformity of the ion beam I, namely, a ratio of an average current value measured by the ion beam profiler 92 in response to irradiation of the ion beam I in a specific local sampling range to an average current value measured by the ion beam profiler 92 in response to irradiation of the ion beam I in the total sampling range, and the uniformity of the ion beam I received by the substrate 91 can be estimated according to the ratio value. An origin position in FIG. 3A is equivalent to a center of the substrate 91. In the embodiment, the ion beam profiler 92 scans and samples the ion beam I along a coordinate axis Y (for example, in the travelling distance of 380 mm, sampling is carried out at 200 scanning positions), and the value of the uniformity of the ion beam I at each position of the substrate 91 along the coordinate axis Y is generally to be close to or equal to 1. In a manufacturing process of a 12-inch wafer, the ion beam height must cover a diameter A of the substrate, namely at least greater than 305 mm. In FIG. 3A, taking the diameter A of a 12-inch substrate as an example, it could be found that the vertical coordinate position is obviously reduced after ±140 mm. When the ion beam height is adjusted, the influence of the ion beam divergence angle θy must be taken into account. In detail, although the uniformity of the ion beam I at an center and an edge of the substrate 91 is close to or equal to 1, The ion beam I bombarding the center of the substrate 91 has a large component of its traveling direction in the direction perpendicular to the substrate 91, resulting in a high implantation depth; and ion beam I bombarding the edge of the substrate 91 has a small component of its traveling direction in the direction perpendicular to the substrate 91, resulting in a low implantation depth. This phenomenon becomes more pronounced when the divergence angle θy of the ion beam is excessively large.

FIG. 3B is a schematic diagram of divergent angles of an ion beam in different axis directions according to some embodiments, and FIG. 1 and FIG. 3B are used for reference. A horizontal axis in FIG. 3B represents the divergence angle of the ion beam I along the coordinate axis X, and a longitudinal axis represents the divergence angle of the ion beam I along the coordinate axis Y. In the embodiment, the ion beam I is a ribbon beam and has a large divergence angle along the coordinate axis Y. The angle measurement Faraday cup 923 of the ion beam profiler 92 can be configured to measure the divergence angle of the ion beam I.

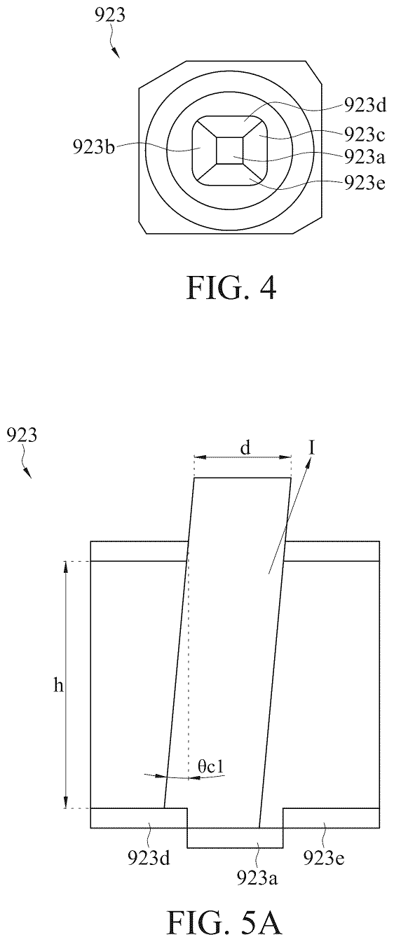

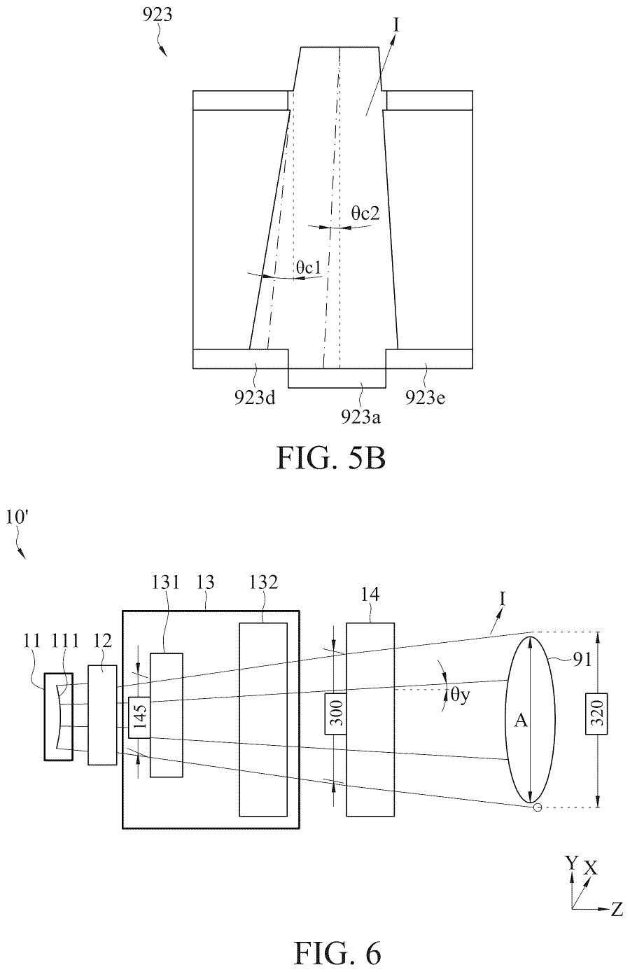

FIG. 4 is a top view schematic diagram of an angle measurement Faraday cup of an ion beam profiler according to some embodiments, FIG. 5A is a schematic diagram of a central angle of an ion beam according to some embodiments, and FIG. 4 and FIG. 5A are used for reference. In the embodiment, the ion beam profiler 92 includes three angle measurement Faraday cups 923 for measuring the divergence angle of the ion beam, the inside of each angle measurement Faraday cup 923 is a chamber, and the ion beam I is emitted into a chamber through the slit at a top of the angle measurement Faraday cup 923 of the ion beam. The chamber has a chamber height h, and the slit has a slit width d. A bottom of each angle measurement Faraday cup 923 sequentially includes a left side sensor 923b, a central sensor 923a and a right side sensor 923c in the X-axis direction. Similarly, an upper side sensor 923d, a central sensor 923a and a lower side sensor 923e are sequentially provided in the Y-axis direction. The central sensor 923a generates a central sensor current Ic in response to the irradiation of the ion beam I, the left side sensor 923b generates a left side sensor current Ix⁺ in response to the irradiation of the ion beam I, the right side sensor 923c generates a right side sensor current Ix⁻ in response to the irradiation of the ion beam I, the upper side sensor 923d generates an upper side sensor current Iy⁺ in response to the irradiation of the ion beam I, and the lower side sensor 923e generates a lower side sensor current Iy⁻ in response to the irradiation of the ion beam I. As shown in FIG. 5A, the lower side sensor 923e does not receive the irradiation of the ion beam I (Iy⁻ is 0), the ion beam I irradiates into the chamber of the angle measurement Faraday cup 923 of the ion beam through the slit at the top, and the ion beam I is deflected toward the upper side sensor 923d. According to the following Formula I, a central angle θc1 of the ion beam in the coordinate axis Y direction can be represented as:

$$\frac{( {I}_{y +} ) - ( {I}_{y -} )}{Ir} \times HW \qquad ( Formula I )$$

Numerators are the difference value ((Iy⁻)−(Iy⁻)) of the value of sensor current Iy⁺ of the upper side sensor 923d and the value of sensor current Iy⁻ of the lower side sensor 923e, Ir is the sum of the upper side sensor current Iy⁺, the central sensor current Ic and the lower side sensor current Iy⁻, HW is a size proportion value and is equal to a ratio of the slit width d of the angle measurement Faraday cup 923 to the chamber height h (namely the distance from an entrance slit to the bottom of the angle measurement Faraday cup 923), and in the embodiment, the value is 0.1. In the embodiment, the travelling direction of the ion beam I measured in a local range is defined by the central angle θc1 of the ion beam. For example, the ion beam profiler 92 is located at any position of the 200 scanning positions, and the travelling direction of the ion beam I in the local range is acquired by sampling through the angle measurement Faraday cup 923. In addition, the values acquired by the plurality of angle measurement Faraday cup 923 can be averaged to obtain the central angle θc1 of the ion beam at the sampling position.

FIG. 5B is a schematic diagram of a divergent angle of an ion beam according to some embodiments, and FIG. 5B is used for reference. The ion beam divergence angle θy can be expressed as:

$${θ}_{c 1} - {θ}_{c 2} \qquad ( Formula II )$$

The central angle θc1 of the ion beam represents an average included angle of the ion beam I in the travelling direction measured in the local range, for example, the measured values of the three angle measurement Faraday cups 923 in FIG. 2 are averaged. The total central angle θc2 of the ion beam is an average value of the central angles of the ion beam at each position measured by the ion beam profiler 92 at the 200 scanning positions, so the computation of the ion beam divergence angle θy is as follows: the total central angle θc2 of the ion beam is subtracted from the central angle θc1 of the ion beam in the local range. By measuring the ion beam divergence angle θy, it can be determined whether the difference between the ion beam divergence angle θy of the ion beam I in the center of the substrate 91 is significant different from the ion beam divergence angle θy of the ion beam I at the edge of the substrate 91, which might result in the problem of uneven implantation depth. By taking FIG. 1 as an example, due to the limitation of the travelling distance of the ion beam I between the linear multipole module 14 and the substrate 91, the linear multipole module 14 must adjust the ion beam I to carry out ion implantation with larger ion beam divergence angle θy so as to cover the range of the substrate 91. This way may frequently cause the problem of uneven implantation depth in the center and edge range of the substrate 91 in a large-size wafer manufacturing process, so the edge part of the substrate 91 cannot be utilized in the subsequent manufacturing process.

FIG. 6 is a schematic diagram of an ion implanter according to an Embodiment II, and FIG. 6 is used for reference. In the embodiment, the ion implanter 10′ includes an ion source 11, an ion beam shape adjustment module 12, an analyzer magnet unit 13 and a linear multipole module 14. The linear multipole module 14 is positioned between the ion source 11 and a substrate 91, the analyzer magnet unit 13 is positioned between the ion source 11 and the linear multipole module 14, and the ion beam shape adjustment module 12 is positioned between the ion source 11 and the analyzer magnet unit 13.

In FIG. 6, the ion beam I emitted from the arc slit 111 has an initial divergence angle, the ion beam divergence angle θy is expanded by the ion beam shape adjustment module 12 and enters the analyzer magnet unit 13, and the analyzer magnet unit 13 has a relatively long travelling distance, so the ion beam height in the embodiment is increased from 145 mm when entering the entrance 131 of the analyzer magnet unit 13 to 300 mm when leaving the entrance 131 of the analyzer magnet unit 13. The ion beam I is diverged by the linear multipole module 14 through the magnetic field, and thus, the ion beam height is increased from 300 mm before entering the linear multipole module 14 to 320 mm when reaching the substrate 91. It is to be noted that, with reference to FIG. 1 and FIG. 6, although the ion beam height is only increased to 145 mm in FIG. 6 from 110 mm at the entrance 131 of the analyzer magnet unit 13 in FIG. 1 by the ion beam shape adjustment module 12, due to the cumulative effect of a relatively long travelling distance of the analyzer magnet unit 13, the ion beam height is increased to 300 mm in FIG. 6 from 240 mm at the exit 132 of the analyzer magnet unit 13 in FIG. 1, and thus, the ion beam height can cover a range of the diameter A of the substrate through the linear multipole module 14 only by slightly adjusting the ion beam divergence angle θy. It is to be known that the ion beam height represented in FIG. 1 and FIG. 6 only refers to comparison of different embodiments and is not used for limiting the ion beam height generated by the ion beam shape adjustment module 12.

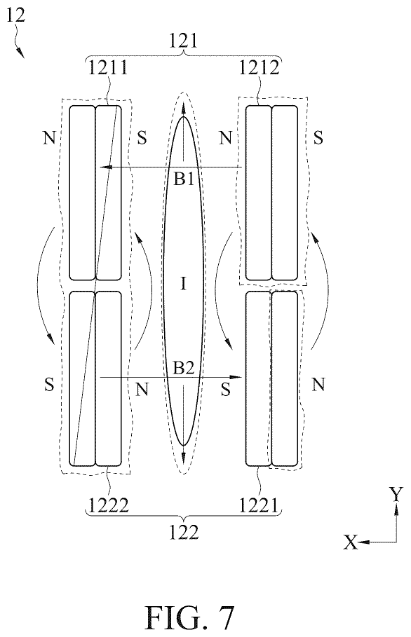

FIG. 7 is a schematic diagram of an ion beam shape adjustment module according to some embodiments, and FIG. 6 and FIG. 7 are used for reference. A coordinate axis Z (a left-right direction in the figure) in FIG. 6 represents the travelling direction of the center of the ion beam I, a coordinate axis X (a direction for penetrating into and out of the figure) represents a left-right direction of the ion implanter 10′, and a coordinate axis Y (an up-down direction in the figure) represents an up-down direction of the ion implanter 10′. Therefore, in FIG. 7, it is equivalent to an observer standing at the position of the arc slit 111 to observe the state of the ion beam I emitted to the substrate 91, namely, the ion beam I shown in FIG. 7 is emitted into the figure. The ion beam shape adjustment module 12 includes an upper magnet pair 121 and a lower magnet pair 122. The upper magnet pair 121 includes a first upper magnet 1211 and a second upper magnet 1212, and the lower magnet pair 122 includes a first lower magnet 1221 and a second lower magnet 1222. The first upper magnet 1211, the second upper magnet 1212, the first lower magnet 1221 or the second lower magnet 1222 can be single magnets, or magnetic units formed by combining a plurality of magnets respectively. As shown in FIG. 7, each magnetic unit includes two magnets. In some embodiments, the first upper magnet 1211, the second upper magnet 1212, the first lower magnet 1221 and the second lower magnet 1222 are permanent magnets, and the size of the magnetic field among the magnet pairs can be adjusted by adjusting the number of the magnets in the magnetic units or a spacing D between the magnet pairs.

As shown in FIG. 7, a first magnetic field B1 is formed between the upper magnet pair 121, a second magnetic field B2 is formed between the lower magnet pair 122, and the travelling direction (the coordinate axis Z, the direction for penetrating into the figure) of the ion beam I is vertical to the first magnetic field B1 or the second magnetic field B2 (the coordinate axis X, the left-right direction in the figure). An upper part of the ion beam I passes through the upper magnet pair 121 and is mainly affected by the first magnetic field B1; and a lower part of the ion beam I passes through the lower magnet pair 122 and is mainly affected by the second magnetic field B2. In order to diverge the ion beam I, the ion beam shape adjustment module 12 can generate an upward magnetic force component to the ion beam I through the first magnetic field B1, and generate a downward magnetic force component to the ion beam I through the second magnetic field B2. In the embodiment, the ion beam I is a positive ion beam includes ions with positive valence number, the first magnetic field B1 points from the right side to the left side relative to the travelling direction (the direction for penetrating into the figure) of the positive ion beam, namely, a magnetic pole N of the second upper magnet 1212 points to a magnetic pole S of the first upper magnet 1211; and the second magnetic field B2 points from the left side to the right side relative to the travelling direction of the positive ion beam, namely, a magnetic pole N of the second lower magnet 1222 points to a magnetic pole S of the first lower magnet 1221. According to the law of Lorentz force, an upper part of the ion beam I is subjected to a positive magnetic force of the coordinate axis Y, and a lower part of the ion beam I is subjected to a negative magnetic force of the coordinate axis Y, and thus, the ion beam I diverges along the axis Y direction.

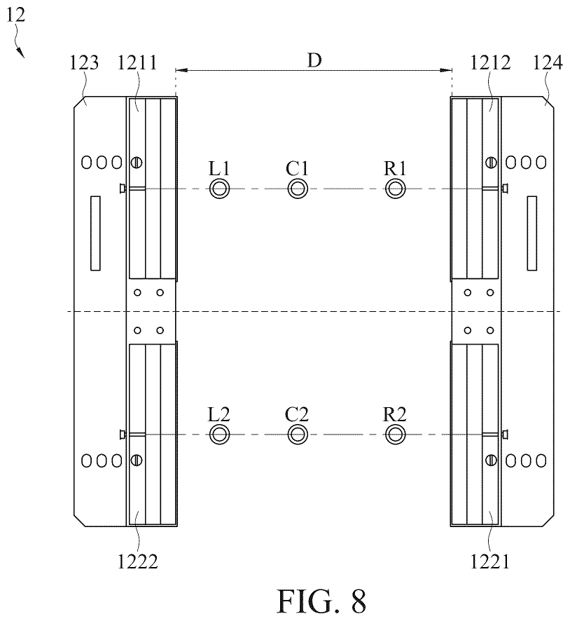

The divergence degree of the ion beam I is influenced by the first magnetic field B1 and the second magnetic field B2, and more precisely, the divergence degree is related to the magnetic flux within a specific curved surface area passed through by the ion beam I. FIG. 8 is a schematic diagram of a plurality of magnetic field measurement points among ion beam shape adjustment modules according to some embodiments, Table 1 is a Gaussian value recording table (listed at the end of the description) of each magnetic field measurement point in the embodiment in FIG. 8, and FIG. 8 and Table 1 are used for reference. The ion beam shape adjustment module 12 in the embodiment includes a left arm 123 and a right arm 124, the first upper magnet 1211 is fixed at an upper part of the left arm 123, the second lower magnet 1222 is fixed at a lower part of the left arm 123, the second upper magnet 1212 is fixed at an upper part of the right arm 124, and the first lower magnet 1221 is fixed at a lower part of the right arm 124. The spacing D between the left arm 123 and the right arm 124 can be adjusted to influence the magnetic flux of each space point between the magnet pairs. For example, when the spacing D between the magnet pairs is 202 mm, the Gaussian value of the measurement point L1 closer to the first upper magnet 1211 is 320, and the Gaussian value of the measurement point C1 farther from the first upper magnet 1211 is 118; and when the spacing D of the magnet pairs is reduced to 162 mm, the Gaussian value of the measurement point L1 closer to the first upper magnet 1211 is 937 with the increase amplitude of 293%, and the Gaussian value of the measurement point C1 farther from the first upper magnet 1211 is 259 with the increase amplitude of 219%. Therefore, the divergence degree of the ion beam I is increased along with the reduction of the spacing D between the magnet pairs. With reference to FIG. 6, when the ion beam I passes through the ion beam shape adjustment module 12 with greater divergence, a reduction of the ion beam divergence angle θy at the position of the substrate 91 can be achieved, so the ion implantation depth on the substrate 91 is more uniform.

Table 2 shows the influence of the change of the magnet spacing D on the Y-axis divergence angle of the ion beam I in the embodiments of different processes. In the embodiment, in Table 2, three processes adopt boron with different implantation energies 5 KeV, 8 KeV and 20 KeV for carrying out ion implantation. The ion beam divergence angle θy in the Y axis represents the ion beam divergence angle θy computed in the coordinate axis Y direction of the ion beam I at the substrate 91 through the above formula. As show in Table 2, when the magnet spacing D in a B5K process is reduced from 202 mm to 162 mm, the ion beam divergence angle θy in the Y axis is reduced from 0.89 degree to 0.42 degree; when the magnet spacing D in a B8K process is reduced from 202 mm to 162 mm, the ion beam divergence angle θy in the Y axis is reduced from 0.33 degree to 0.20 degree; and when the magnet spacing D in a B20K process is reduced from 202 mm to 162 mm, the ion beam divergence angle θy in the Y axis is reduced from 0.18 degree to 0.00 degree. As shown in the above embodiments, when the ion beam shape adjustment module 12 reduces the spacing D between the magnet pairs to increase the ion beam divergence angle θy, the required adjustment of ion beam divergence angle θy at the position of the linear multipole module 14 is reduced. This results in a reduced ion beam divergence angle θy measured near the substrate 91 (at the position of the ion beam profiler 92).

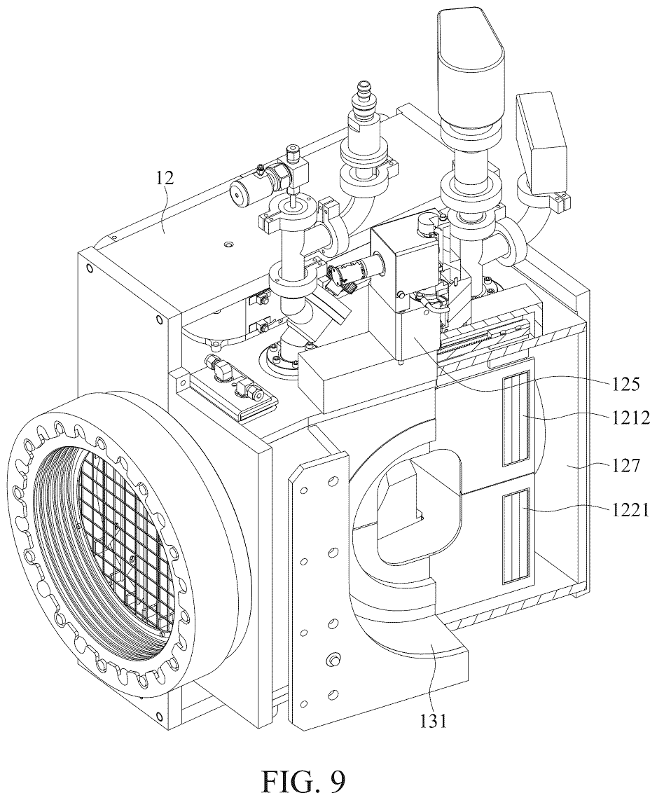

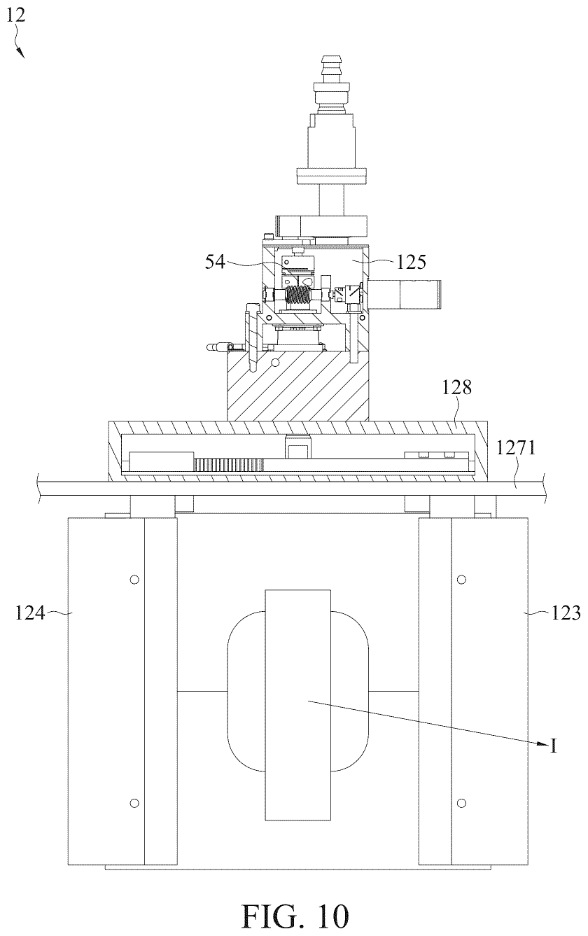

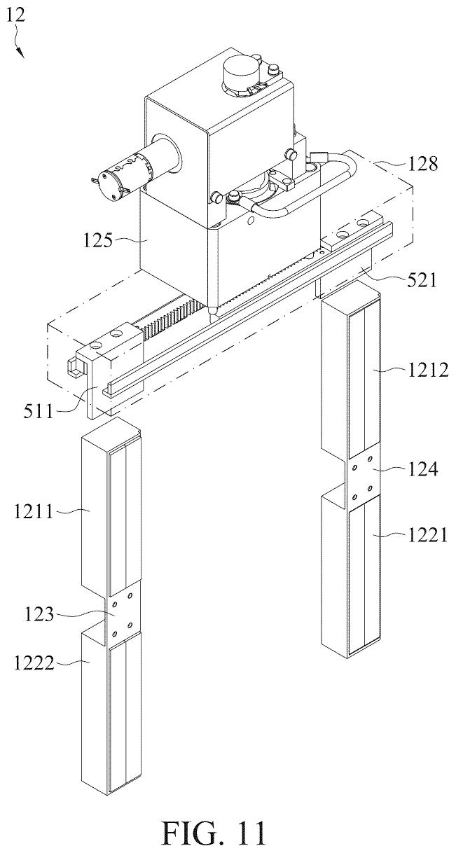

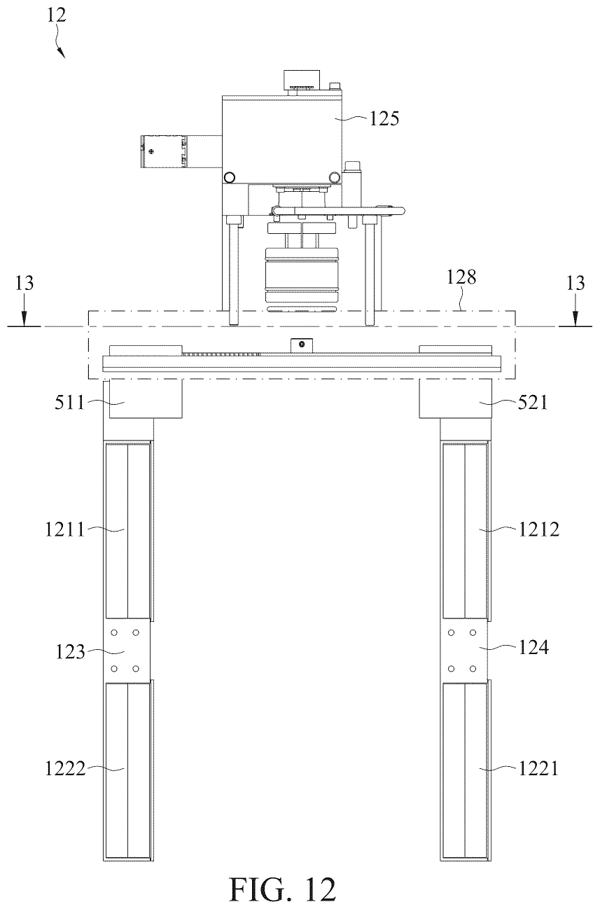

FIG. 9 is a three-dimensional schematic diagram of a vacuum chamber according to an Embodiment III; FIG. 10 is a front view schematic diagram of a vacuum chamber according to an Embodiment III; FIG. 11 is a three-dimensional schematic diagram of an ion beam shape adjustment module according to an Embodiment III; and FIG. 12 is a front view schematic diagram of an ion beam shape adjustment module according to an Embodiment III, and FIG. 9 to FIG. 12 are used for reference. In the embodiment, the ion beam shape adjustment module 12 is positioned at the entrance 131 of the analyzer magnet unit 13, and the ion beam shape adjustment module 12 includes a vacuum chamber 127, the upper magnet pair 121, the lower magnet pair 122, the left arm 123, the right arm 124 and a driver 125. The left arm 123 and the right arm 124 are configured to fix the upper magnet pair 121 and the lower magnet pair 122 respectively and are positioned in the vacuum chamber 127. The driver 125 is coupled to the left arm 123 and the right arm 124 and is configured to adjust the spacing D between the left arm 123 and the right arm 124. Part of components of the driver 125 are arranged outside the vacuum chamber 127 to facilitate equipment maintenance. In detail, as shown in FIG. 10, the left arm 123 and the right arm 124 are respectively positioned at the left side and the right side relative to a path of the ion beam I, a chamber wall 1271 at an upper part of the vacuum chamber 127 includes an opening, and upper ends of the left arm 123 and the right arm 124 penetrate through the opening and are coupled to the driver 125. In order to keep the sealing status of the vacuum chamber 127, the opening in the chamber wall 1271 is covered by a sealing cover 128. Therefore, a slide rail mechanism of the driver 125 is surrounded by the sealing cover 128, and a motor set 54 is fixed on the sealing cover 128.

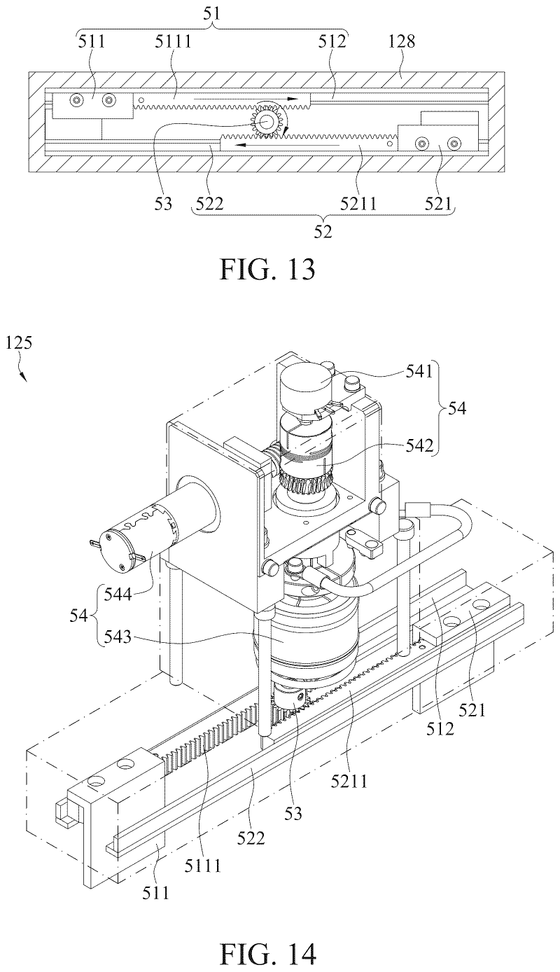

FIG. 13 is a top view schematic diagram of an ion beam shape adjustment module according to an Embodiment III; and FIG. 14 is a three-dimensional schematic diagram of a driver of an ion beam shape adjustment module according to an Embodiment III, and FIG. 13 and the FIG. 14 are used for reference. In the embodiment, the driver 125 of the ion beam shape adjustment module 12 includes a first slide rail 51, a second slide rail 52, a gear 53 and a motor set 54. The first slide rail 51 includes a first sliding block 511 and a first guide rail 512, and the first sliding block 511 includes a rack 5111. The second slide rail 52 includes a second sliding block 521 and a second guide rail 522, and the second sliding block 521 includes a rack 5211. The first guide rail 512 and the second guide rail 522 according to the embodiment are oppositely positioned in parallel, and the extending direction of the first guide rail or the second guide rail is substantially parallel to the direction of the first magnetic field B1. In other words, the first guide rail 512 and the second guide rail 522 are suitable for enabling the left arm 123 and the right arm 124 to get away from or get close to each other. The gear 53 is simultaneously meshed with the rack 5111 of the first sliding block 511 and the rack 5211 of the second sliding block 521. As shown in FIG. 13, when the gear 53 rotates clockwise, the rack 5111 of the first sliding block 511 is driven to move rightwards, and thus the first sliding block 511 and the left arm 123 coupled to the first sliding block 511 are made to move rightwards; and the rack 5211 of the second sliding block 521 is driven to move leftwards, and thus the second sliding block 521 and the right arm 124 coupled to the second sliding block 521 are made to move leftwards. Therefore, the left arm 123 and the right arm 124 get close to each other, so that magnetic force acting on the ion beam I is increased. Otherwise, when the gear 53 rotates anticlockwise, the rack 5111 of the first sliding block 511 is driven to move leftwards, and thus the first sliding block 511 and the left arm 123 coupled to the first sliding block 511 are made to move leftwards; and the rack 5211 of the second sliding block 521 is driven to move rightwards, and thus the second sliding block 521 and the right arm 124 coupled to the second sliding block 521 are made to move rightwards. Therefore, the left arm 123 and the right arm 124 get away from each other, so that the magnetic force acting on the ion beam I is reduced.

As shown in FIG. 13, in the embodiment, the gear 53 is driven by the motor set 54 to rotate, the motor set 54 is fixed outside the vacuum chamber 127, and a rotating shaft of the motor set 54 penetrates through the sealing cover 128 and is fixedly connected to the gear 53. The motor set 54 according to the embodiment includes a variable resistor 541, a worm and worm wheel set 542, a hydro-magnetic bearing 543 and a driving motor 544. The driving motor 544 is configured to generate a torsion, and the worm and worm wheel set 542 is driven by the driving motor 544 and changes the direction of a torsion to correspond to an axial direction of the gear 53. The hydro-magnetic bearing 543 is configured to seal the opening in the sealing cover 128 so as to facilitate the extension of the rotating shaft of the motor set 54 from an outside of the vacuum chamber 127 to an inside of the vacuum chamber 127. In addition, the hydro-magnetic bearing 543 provides a rotation smoothness for the rotating shaft. The variable resistor 541 is configured to measure a rotation angle of the rotating shaft, thereby calculating the movement distance of the left arm 123 and the right arm 124 and the spacing D between the left arm and the right arm.

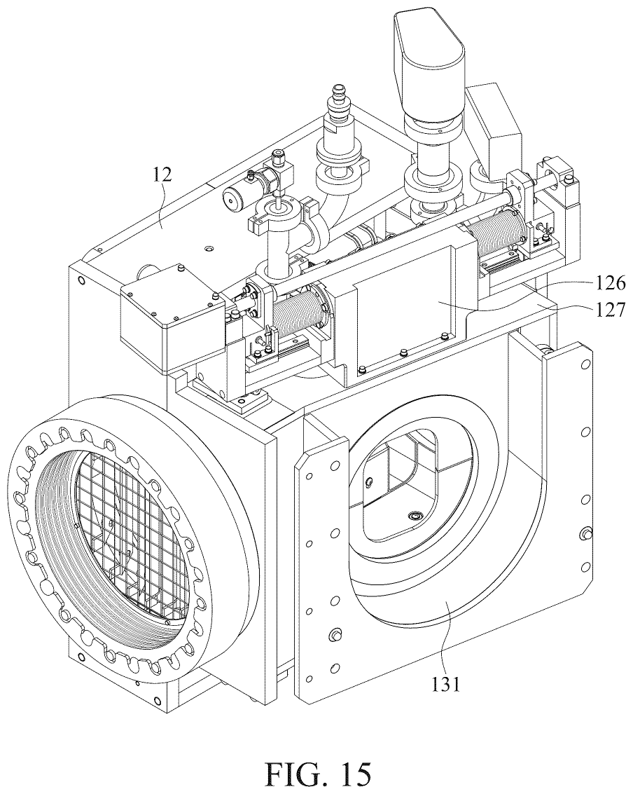

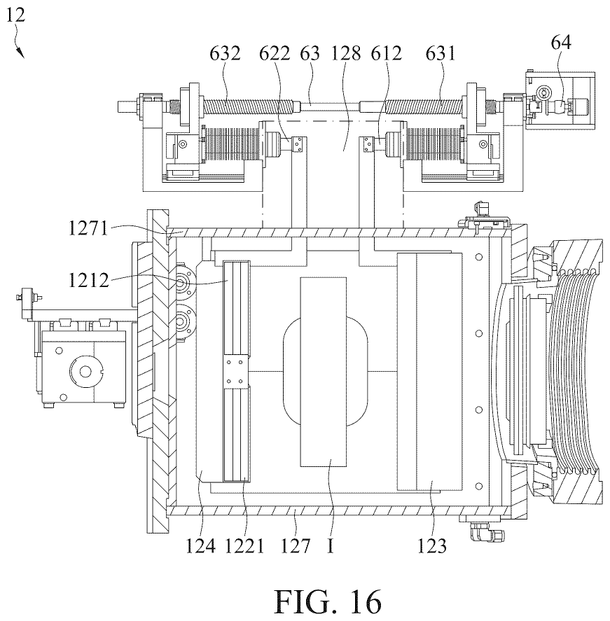

FIG. 15 is a three-dimensional schematic diagram of a vacuum chamber according to an Embodiment IV; and FIG. 16 is a front view schematic diagram of a vacuum chamber according to an Embodiment IV, and the FIG. 15 and FIG. 16 are used for reference. In the embodiment, the ion beam shape adjustment module 12 is positioned at the entrance 131 of the analyzer magnet unit 13, and the ion beam shape adjustment module 12 includes a vacuum chamber 127, the upper magnet pair 121, the lower magnet pair 122, the left arm 123, the right arm 124 and a driver 126. The left arm 123 and the right arm 124 are configured to fix the upper magnet pair 121 and the lower magnet pair 122 respectively and are positioned in the vacuum chamber 127. The driver 126 is coupled to the left arm 123 and the right arm 124 and is configured to adjust the spacing D between the left arm 123 and the right arm 124. Part of components of the driver 126 are positioned outside the vacuum chamber 127. In detail, as shown in FIG. 16, the left arm 123 and the right arm 124 are respectively positioned at the left side and the right side relative to a path of the ion beam I, a chamber wall 1271 at an upper part of the vacuum chamber 127 includes an opening, and upper ends of the left arm 123 and the right arm 124 penetrate through the opening and are coupled to the driver 126. In order to keep the sealing status of the vacuum chamber 127, the opening in the chamber wall 1271 is covered by a sealing cover 128. The differences between this embodiment IV and the Embodiment III include at least the follows: in the embodiment IV, the guide rail structure is positioned outside the vacuum chamber 127, facilitates the device maintenance. In addition, the interference of the ion beam I with the mechanism, which could cause structural damage or generate free particles in the vacuum chamber 127, is avoided.

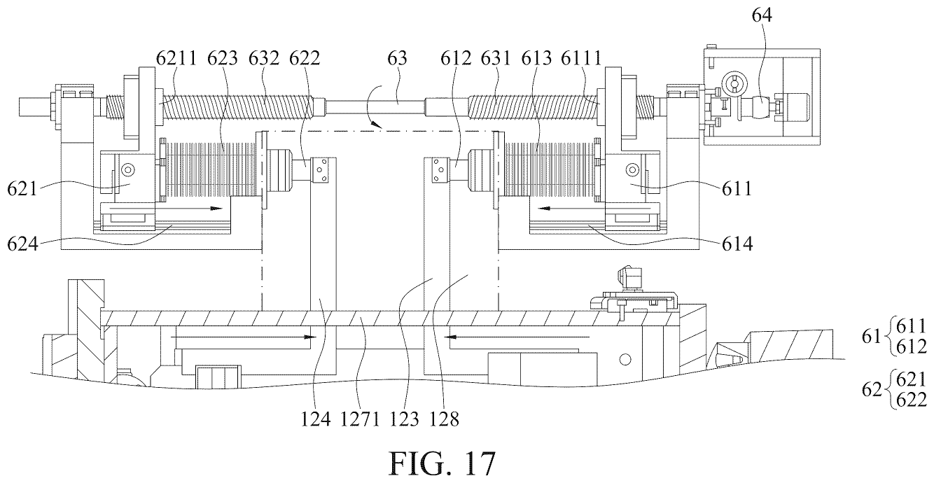

FIG. 17 is a front view schematic diagram of a driver of an ion beam shape adjustment module according to an Embodiment IV, and FIG. 17 is used for reference. In the embodiment, the driver 126 of the ion beam shape adjustment module 12 includes a first sliding table 61, a second sliding table 62, a screw 63 and a motor set 64. The first sliding table 61 includes a first pulley 611 and a first connecting rod 612, the first pulley 611 is coupled to the first connecting rod 612 and includes a screw hole 6111, and the first connecting rod 612 penetrates through the vacuum chamber 127 and is fixedly connected to the left arm 123. The second sliding table 62 includes a second pulley 621 and a second connecting rod 622, the second pulley 621 is coupled to the second connecting rod 622 and includes a screw hole 6211, and the second connecting rod 622 penetrates through the vacuum chamber 127 and is fixedly connected to the right arm 124. The first connecting rod 612 and the second connecting rod 622 according to the embodiment are positioned in parallel, and the extending direction of the first connecting rod or the second connecting rod is substantially parallel to the direction of the first magnetic field B1. In other words, the first connecting rod 612 and the second connecting rod 622 are suitable for enabling the left arm 123 and the right arm 124 to get away from or get close to each other. The screw 63 extends in a direction parallel to the first connecting rod 612 or the second connecting rod 622 and penetrates through the screw hole 6111 of the first pulley 611 and the screw hole 6211 of the second pulley 621 simultaneously. As shown in FIG. 17, a left thread 631 (the surface area of the screw 63 penetrating through the screw hole 6111 of the first pulley 611) of the screw 63 has a first thread direction, a right thread 632 (the surface area of the screw 63 penetrating through the screw hole 6211 of the second pulley 621) of the screw 63 has a second thread direction, and the first thread direction of the left thread 631 is opposite to the second thread direction of the right thread 632. Thus, when the motor set 64 drives the screw 63 to rotate anticlockwise, the screw hole 6111 of the first pulley 611 is engaged, causing the first pulley 611 to move left along the first guide rail 614 in FIG. 17, thus, the left arm 123 coupled to the first pulley 611 through the first connecting rod 612 moves left in the FIG. 17; and the screw hole 6211 of the second pulley 621 is engaged, causing the second pulley 621 to move right along the second guide rail 624 in FIG. 17, thus, the right arm 124 coupled to the second pulley 621 through the second connecting rod 622 moves right in FIG. 17. Therefore, the left arm 123 and the right arm 124 get close to each other, so that magnetic force acting on the ion beam I is increased.

In some embodiments, the driver 126 includes a first bellow 613 and a second bellow 623, the first bellow 613 wraps the first connecting rod 612 and is fixedly connected to the first pulley 611 and the chamber wall 1271 of the vacuum chamber 127, and the second bellow 623 wraps the second connecting rod 622 and is fixedly connected to the second pulley 621 and the chamber wall 1271 of the vacuum chamber 127. The bellows are configured to seal the opening in the sealing cover 128, so that the first connecting rod 612 or the second connecting rod 622 can extend into the vacuum chamber 127 from an outside of the vacuum chamber 127. In addition, the bellows have compressibility, provides the mobility of the first connecting rod 612 or the second connecting rod 622.

Although the present disclosure has been described as above by way of embodiments, it is not used to limit the present disclosure. Any person with ordinary skill in the art can make slight variations and modifications without departing from the spirit and scope of the present disclosure. Therefore, the scope of protection of the present disclosure shall be subject to the scope defined in the attached patent application.

TABLE 1
Gaussian value record table of each magnetic field
measurement point in embodiment in FIG. 8

| Measurement | Spacing between magnet pairs (mm) | | Increase |
|---|---|---|---|
| points | 202 | 162 | amplitude |
| L1 | 320 | 937 | 293% |
| L2 | −320 | −937 | 293% |
| C1 | 118 | 259 | 219% |
| C2 | −118 | −259 | 219% |
| R1 | 320 | 937 | 293% |
| R2 | −320 | −937 | 293% |

TABLE 2
Table of change of magnet spacing relative to change of ion
beam divergence angle in Y axis in different processes

| Spacing between magnet pairs (mm) | 202 | 162 |
|---|---|---|
| Ion beam divergence angle in Y axis-B5K | 0.89 | 0.42 |
| Ion beam divergence angle in Y axis-B8K | 0.33 | 0.20 |
| Ion beam divergence angle in Y axis-B20K | 0.18 | 0.00 |

What is claimed is:

1. An ion implanter, configured to process a substrate, comprising:
an ion source, configured to generate an ion beam;
a linear multipole module positioned between the ion source and the substrate, and configured to diverge the ion beam;
an ion beam shape adjustment module, positioned between the ion source and the linear multipole module; and
an analyzer magnet unit, positioned between the ion source and the linear multipole module, the ion beam shape adjustment module being positioned in front of an entrance of the analyzer magnet unit, and the linear multipole module being positioned behind an exit of the analyzer magnet unit, wherein
the ion beam shape adjustment module is configured to adjust the ion beam to modify an ion beam divergence angle as the ion beam enters the substrate.

2. The ion implanter according to claim 1, wherein the ion beam shape adjustment module is configured to generate a first magnetic field and a second magnetic field, and the ion beam passes through the first magnetic field and the second magnetic field simultaneously, a magnetic field direction of the first magnetic field being opposite to the second magnetic field.

3. The ion implanter according to claim 2, wherein the ion beam shape adjustment module comprises:
an upper magnet pair, configured to generate the first magnetic field, wherein the upper magnet pair further comprises a first upper magnet and a second upper magnet, a first gap is formed between the first upper magnet and the second upper magnet, an upper part of the ion beam passes through the first gap, and a travelling direction of the ion beam is vertical to the first magnetic field; and
a lower magnet pair comprising a first lower magnet and a second lower magnet, wherein the second magnetic field is formed between the lower magnet pair, a second gap is formed between the first lower magnet and the second lower magnet, a lower part of the ion beam passes through the second gap, and a travelling direction of the ion beam is vertical to the second magnetic field.

4. The ion implanter according to claim 3, wherein the first magnetic field generates an upward magnetic force component to the ion beam, and the second magnetic field generates a downward magnetic force component to the ion beam.

5. The ion implanter according to claim 3, wherein the first upper magnet, the second upper magnet, the first lower magnet and the second lower magnet are permanent magnets.

6. The ion implanter according to claim 3, wherein a spacing between the first gap or the second gap is in direct proportion to the ion beam divergence angle.

7. The ion implanter according to claim 3, wherein the ion beam shape adjustment module further comprises:
a left arm, positioned on the left side relative to the travelling direction of the ion beam, wherein the first upper magnet is fixed at an upper part of the left arm, and the second lower magnet is fixed at a lower part of the left arm;
a right arm, positioned on the right side relative to the travelling direction of the ion beam, wherein the second upper magnet is fixed at an upper part of the right arm, and the first lower magnet is fixed at a lower part of the right arm; and
a driver, coupled to the left arm and the right arm, and configured to adjust a spacing between the left arm and the right arm.

8. The ion implanter according to claim 7, wherein the ion beam shape adjustment module further comprises a vacuum chamber; the left arm and the right arm are arranged in the vacuum chamber; and the driver comprises:
a first slide rail, comprising a first sliding block and a first guide rail, wherein the first guide rail extends in a direction parallel to the first magnetic field, and the first sliding block is coupled to the left arm and comprises a rack;
a second slide rail, comprising a second sliding block and a second guide rail, wherein the second guide rail extends in the direction parallel to the first magnetic field and is positioned on an opposite side of the first guide rail, and the second sliding block is coupled to the right arm and comprises an another rack;
a gear, simultaneously meshed with the rack of the first sliding block and the another rack of the second sliding block; and
a motor set, fixed on an outer side of the vacuum chamber, wherein a rotating shaft of the motor set penetrates through a chamber wall of the vacuum chamber and is fixedly connected to the gear.

9. The ion implanter according to claim 7, wherein the ion beam shape adjustment module further comprises a vacuum chamber; the left arm and the right arm are arranged in the vacuum chamber; and the driver comprises:
a first sliding table, comprising a first pulley and a first connecting rod, wherein the first sliding table is positioned outside the vacuum chamber, the first connecting rod extends in a direction parallel to the first magnetic field, penetrates through a chamber wall of the vacuum chamber and is fixedly connected to the left arm, and the first pulley is coupled to the first connecting rod and comprises a screw hole;
a second sliding table, comprising a second pulley and a second connecting rod, wherein the second sliding table is positioned outside the vacuum chamber, the second connecting rod extends in the direction parallel to the first magnetic field, penetrates through the chamber wall of the vacuum chamber and is fixedly connected to the right arm, and the second pulley is coupled to the second connecting rod and comprises an another screw hole;
a screw, extending a direction parallel to the first connecting rod and the second connecting rod and penetrating through the screw hole of the first pulley and the another screw hole of the second pulley simultaneously; and
a motor set, comprising a rotating shaft, and being fixedly connected to one side of the screw.

10. The ion implanter according to claim 9, wherein the screw has a first thread at an area passing through the screw hole of the first pulley and has a second thread at another area passing through the another screw hole of the second pulley, and the direction of the first thread is opposite to the direction of the second thread.

11. The ion implanter according to claim 9, wherein the driver further comprises a first bellow and a second bellow, the first bellow wraps the first connecting rod and is fixedly connected to the first pulley and the chamber wall of the vacuum chamber, and the second bellow wraps the second connecting rod and is fixedly connected to the second pulley and the chamber wall of the vacuum chamber.
